(19) United States
(12) Patent Application Publication
(10) Pub. No.: US 2015/0143926 A1
(43) Pub. Date: May 28, 2015

(54) AREA-EFFICIENT PRESSURE SENSING DEVICE

(71) Applicant: Silicon Microstructures, Inc., Milpitas, CA (US)

(72) Inventor: Holger Doering, Sunnyvale, CA (US)

(73) Assignee: Silicon Microstructures, Inc., Milpitas, CA (US)

(21) Appl. No.: 14/088,397

(22) Filed: Nov. 23, 2013

(51) Int. Cl. G01L 1/22; H01L 21/52; G01L 1/04

(52) U.S. Cl. CPC G01L 1/2287; G01L 1/04; G01L 1/225; H01L 21/52
USPC 73/862.629; 438/51

(57) ABSTRACT

Circuits, methods, and apparatus that provide pressure sensing devices having a pressure sensor including a diaphragm supported by a frame. The pressure sensor may be mounted on an application-specific integrated circuit. A passage may extend through the application-specific integrated circuit from its underside to its topside where it may terminate in a cavity formed under the diaphragm. Circuit components may be formed in the second wafer portion and located in areas that are not under the first wafer portion. Circuit components may be formed in the second wafer in areas under the first wafer portion, such as under the frame or under the diaphragm. Circuit components may be formed in the second wafer such that they are partially under the first wafer portion, or partially under the frame or partially under the diaphragm.

### BACKGROUND

Pressure sensing devices have become ubiquitous the past few years as they have found their way into several types of products. Utilized in automotive, industrial, consumer, and medical products, the demand for pressure sensing devices has skyrocketed and shows no signs of abating.

Pressure sensing devices may include pressure sensors as well other components. Pressure sensors may typically include a diaphragm or membrane. When a pressure sensor in a pressure sensing device experiences a pressure, the membrane responds by changing shape. This change in shape causes one or more characteristics of electronic components on the membrane to change. These changing characteristics can be measured, and from this the pressure can be determined.

Often, the electronic components are resistors configured as a Wheatstone bridge located on the membrane of a pressure sensor. As the membrane distorts due to a pressure, the resistance of the resistors change. This change results in an output of the Wheatstone bridge. This change can be measured through wires or leads attached to the resistors.

These pressure sensors may communicate with other circuits to form pressure sensing devices. These other circuits may be formed on a separate chip packaged apart from the pressure sensors. Other pressure sensing devices may include pressure sensors and the other circuits formed as a single integrated circuit. This provides a distinct area efficiency advantage over separate devices in separate packages.

But pressure sensors may often be manufactured using a simpler, lower cost process than what is used to form circuitry on an integrated circuit. When what should be a relatively low-cost pressure sensor is formed on a relatively more expensive integrated circuit, the cost of the pressure sensor, and thus the pressure sensing device, is increased. Further, if a pressure sensor on a combined pressure sensing device integrated circuit fails at testing, the entire integrate circuit fails, thereby reducing yield and again increasing costs.

Thus, what are needed are circuits, methods, and apparatus that provide pressure sensing devices that are area efficient and may take advantage of low-cost pressure sensor manufacturing techniques.

### SUMMARY

Accordingly, embodiments of the present invention may provide circuits, methods, and apparatus that provide pressure sensing devices that are area efficient and may take advantage of low-cost pressure sensor manufacturing techniques.

An illustrative embodiment of the present invention may provide an area efficient pressure sensing device by providing a device where a pressure sensor is stacked on an application-specific integrated circuit that includes other circuitry for the pressuring sensing device. A pressure sensor may be formed as a first die. An application-specific integrated circuit that includes other circuitry may be formed as a second die. The first die may be attached to a top of the second die. This may form an area-efficient pressure sensing device that may be housed in a single integrated circuit or other appropriate package or module. The first and second die may have pads electrically connected together, and pads on either or both the first and second die may be electrically connected to contacts on the integrated circuit package. In various embodiments of the present invention, the pressure sensing device may be a gauge pressure sensor where a passage through the application-specific integrated circuit may allow a fluid to reach a cavity formed under a diaphragm of the pressure sensor. The pressure of the fluid is then determined by deflection of the diaphragm caused by a difference in pressure between the fluid under the diaphragm and a reference pressure at a top surface of the diaphragm.

An illustrative embodiment of the present invention may provide a pressure sensing device including a pressure sensor and an application-specific integrated circuit where the pressure sensor may be stacked on the application-specific integrated circuit. The pressure sensor may be formed using a lower-cost manufacturing process, while the application-specific integrated circuit may be formed using a higher-cost manufacturing process. In this way, each of the pressure sensor and an application-specific integrated circuit may be formed using an appropriate process, thereby reducing overall costs. In particular, a relatively large pressure sensor diaphragm is not placed on the application-specific integrated circuit, which would decrease transistor density and increase the cost for each application-specific integrated circuit. Further, each time a pressure sensing device has a yield issue, the more expensive application-specific integrated circuits are not lost. Also, this stacked arrangement may provide a smaller footprint than having multiple devices in one or more integrated circuit packages, thereby allowing the use of smaller and possibly less-expensive packages or modules.

An illustrative embodiment of the present invention may provide a pressure sensing device including a pressure sensor and an application-specific integrated circuit where the pressure sensor may be stacked on the application-specific integrated circuit. The pressure sensor may be formed having a frame surrounding a diaphragm formed in a top of the pressure sensor. The pressure sensor may have a cavity formed under the diaphragm. One or more circuits or components may be formed in or on the diaphragm. For example, a Wheatstone bridge may be formed in or on the diaphragm. One or more pads, solder bumps, or other structures may be formed on or near the frame.

The application-specific integrated circuit may be formed to include a number of circuits. One or more pads, solder bumps, or other structures may be formed on the application-specific integrated circuit. A passage may be formed from a bottom side to a top side of the application-specific integrated circuit. The passage may be formed using a deep-reactive ion etch, by micro-machining, or by using another appropriate technique. In various embodiments of the present invention, the application-specific integrated circuit may be thinned to reduce etch times and reduce costs.

The pressure sensor may be aligned to the application-specific integrated circuit such that the passage through the application-specific integrated circuit terminates in the cavity under the diaphragm of the pressure sensor. This may allow a continuous flow path from the underside of the application-specific integrated circuit through the passage in the application-specific integrated circuit and into the cavity in the underside of the diaphragm of the pressure sensor. The pressure sensor may be attached to a top of the application-specific integrated circuit using silicone to reduce stress coupling between the application-specific integrated circuit and the diaphragm. The silicone may be RTV silicone or other type of silicone. In other embodiments of the present invention, other adhesives, such as epoxy, may be used. Bond wires, solder bumps, or other techniques may be used to form electrical connections between pads or other structures on the pressure sensor and application-specific integrated circuit, between pads or other structures on the pressure sensor and contacts, pins, or other structures of an integrated circuit or other package, and between pads or other structures on the application-specific integrated circuit and contacts, pins, or other structures of the integrated circuit or other package. In still other embodiments of the present invention, pads on an underside of a pressure sensor may attach to pads on a top surface of an application-specific integrated circuit. An example of such a pressure sensor can be found in co-pending U.S. patent application Ser. No. 13/674,883, titled PRESSURE SENSING DEVICE HAVING CONTACTS OPPOSITE A MEMBRANE, by Gaynor, filed Nov. 12, 2012, which is incorporated by reference.

In various embodiments of the present invention, the application-specific integrated circuit may include various circuits and components, such as amplifiers, analog-to-digital converters, digital-to-analog converters, multiplexers, memory for storing compensation coefficients of the pressure sensor, logic components for formulating equations based on these coefficients, memory for unique part or vendor identification, power regulators, and other types of circuits and components.

In various embodiments of the present invention, components for the application-specific integrated circuit may be placed in various locations on the application-specific integrated circuit. For example, circuits may be formed in or on the application-specific integrated circuit in areas that are not covered by the pressure sensor. In these and other embodiments, circuits may be formed under the cavity of the pressure sensor. In these and other embodiments, circuits may be formed under the frame of the pressure sensor. In these and other embodiments, circuits may be formed at least partially under the frame or at least partially under the diaphragm. In various embodiments of the present invention, circuit components may be formed in the application-specific integrated circuit. Various components may be attached to a top, sides, or bottom of the application-specific integrated circuit and the pressure sensor.

An illustrative embodiment of the present invention may provide a method of manufacturing a pressure sensing device. This method may include forming a first wafer portion or die that includes a pressure sensor. A second wafer portion or die comprising an application-specific integrated circuit may be formed. The application-specific integrated circuit may have a passage from a bottom side a top side of the application-specific integrated circuit. A bottom of the first wafer portion may be attached to a top of the second wafer portion such that an opening of the passage in the top side of the second wafer portion is under the first wafer portion, for example, it may be under the diaphragm of the first wafer portion.

Various embodiments of the present invention may incorporate one or more of these and the other features described herein. A better understanding of the nature and advantages of the present invention may be gained by reference to the following detailed description and the accompanying drawings.

### BRIEF DESCRIPTION OF THE DRAWINGS

FIG. 1 illustrates a pressure sensing device according to an embodiment of the present invention;

FIG. 2 illustrates a side-view of a pressure sensing device according to an embodiment of the present invention;

FIG. 3 is a bottom-view illustrating portions of a pressure sensing device according to an embodiment of the present invention;

FIG. 4 is a top view illustrating portions of a pressure sensing device according to an embodiment present invention;

FIG. 5 illustrates a pressure sensor being placed on an application-specific integrated circuit according to an embodiment of the present invention;

FIG. 6 illustrates a portion of a pressure sensor according to an embodiment of the present invention; and

FIG. 7 illustrates a side view of a pressure sensing device according to an embodiment of the present invention.

### DESCRIPTION OF ILLUSTRATIVE EMBODIMENTS

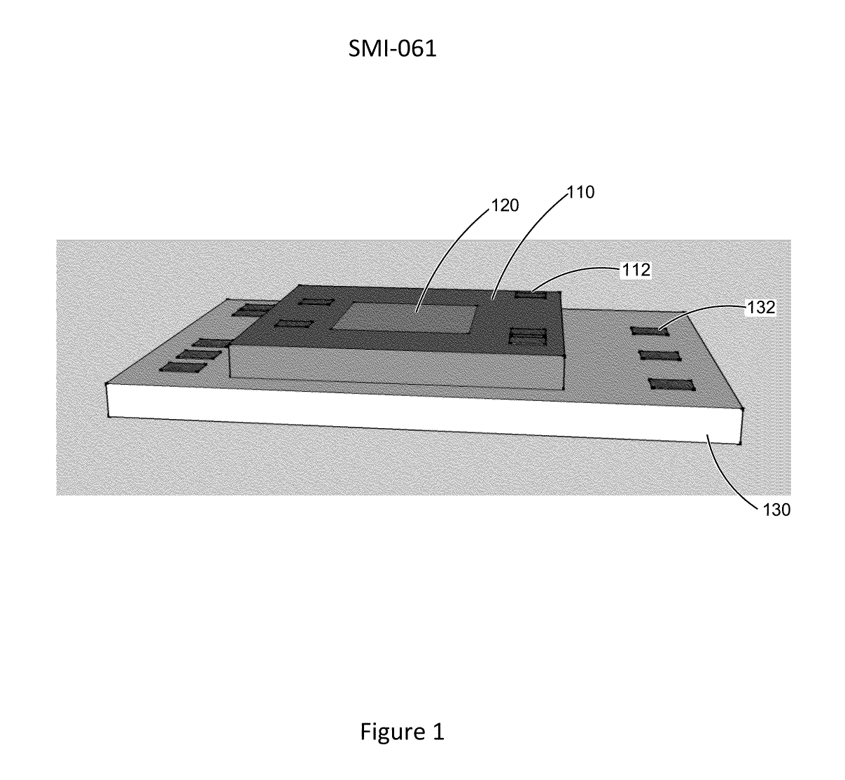

FIG. 1 illustrates a pressure sensing device according to an embodiment of the present invention. This figure, as with the other included figures, is shown for illustrative purposes and does not limit either the possible embodiments of the present invention or the claims.

This figure illustrates a pressure sensing devices that includes a first die 110 attached to a second die 130. The first die or wafer portion 110 may be a pressure sensor including a diaphragm 120 surrounded by a frame. One or more pads 112 may be located on or near the frame of pressure sensor 110. One or more pressure sensing components, such as resistors for Wheatstone bridge, transistors, or other components or circuits, may be located on or near diaphragm 120. The second die or wafer portion 130 may be an application-specific integrated circuit. Application-specific integrated circuit 130 may include one or more pads 132.

Pads 112 and 132 may be used to connect pressure sensor 110 and application-specific integrated circuit 130 to each other and to a frame of an integrated circuit package, module, or other type of package. While pads 112 and 132 are shown in this example, in other embodiments of the present invention, other types of structures, such as solder bumps and other types of contacts, may be employed on either or both pressure sensor 110 and application-specific integrated circuit 130. Also, while in this example, pressure sensor 110 is shown as being smaller than application-specific integrated circuit 130 in both an X and Y dimension, in other embodiments of the present invention, pressure sensor 110 may be the same size or larger than application-specific integrated circuits 130 and one or more of the X and Y dimensions.

Also, while pads 112 are shown as being on a top surface of pressure sensor 110, in other embodiments of the present invention, pads 112 may be located on a bottom of pressure sensor 110. Examples of such pressure sensors can be found in co-pending U.S. patent application Ser. No. 13/674,883, titled PRESSURE SENSING DEVICE HAVING CONTACTS OPPOSITE A MEMBRANE, by Gaynor, filed Nov. 12, 2012, which is incorporated by reference.

Again, embodiments of the present invention may provide pressure sensing devices that include application-specific integrated circuits. Various types of circuits may be formed on or in the application-specific integrated circuit, such as, amplifiers, analog-to-digital converters, digital-to-analog converters, multiplexers, memory for storing compensation coefficients of the pressure sensor, logic components for formulating equations based on these coefficients, memory for unique part or vendor identification, power regulators, and other types of circuits and components. In various embodiments of the present invention, these circuits may be located at various locations on the application-specific integrated circuit. An example is shown in the following figure.

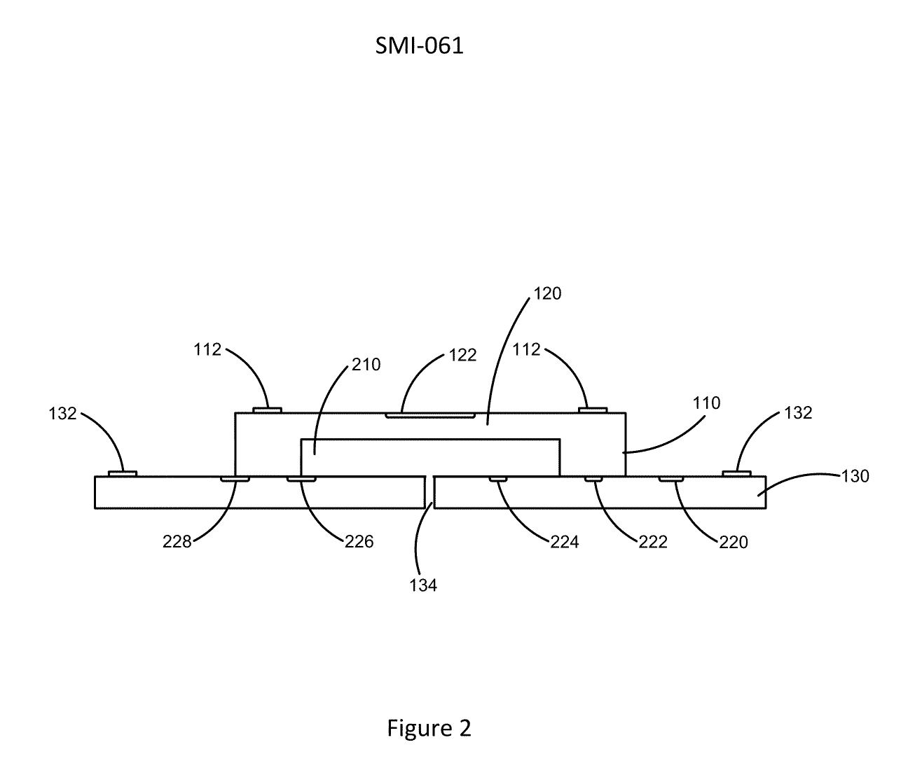

FIG. 2 illustrates a side-view of a pressure sensing device according to an embodiment of the present invention. In this example, the pressure sensing device is a gauge pressure sensing device where a fluid to be measured may flow through passage 134 into cavity 210, where its pressure may be measured using one or more components 122 on diaphragm 120. More specifically, a difference in pressure between the fluid in cavity 210 and a pressure at a top surface of diaphragm 120 may cause a deflection in the diaphragm, which may be measured by components on or near diaphragm 120.

Again, a first die or wafer portion 110 may be attached to a second die or wafer portion 130. The first wafer portion 110 may be a pressure sensor including a diaphragm 120 surrounded by a frame. Cavity 210 may be defined by an underside of diaphragm 120, an inner sidewall of the frame, and a top surface of application-specific integrated circuit 130. One or more pads 112 may be arranged on the frame. One or more components, such as resistor 122, may be located on diaphragm 120.

Application-specific integrated circuit 130 may include passage 134. Passage 134 may allow an uninterrupted flow of fluid from an underside of the pressure sensing device into cavity 210. Passage 134 may be formed using a deep-reactive ion etch, by micro-machining, or by other appropriate technique.

Application-specific integrated circuit 130 may include various components along a top (or other) surface. For example, one or more components 220 may be located on application-specific integrated circuit 130 in an area that is not covered by pressure sensor 120. Other components, such as component 222, may be located on application-specific integrated circuit 130 in an area under frame 110. Other components, such as components 224, may be located on application-specific integrated circuit 130 under diaphragm 120. Still other components, such as component 226, may be at least partially located under the frame and partially under diaphragm 120, while other components, such as components 228, may be at least partially located under the frame of pressure sensor 120 and partly not covered by pressure sensor 120.

Again, embodiments of the present invention may provide gauge pressure sensing devices. An example is shown in the following figure.

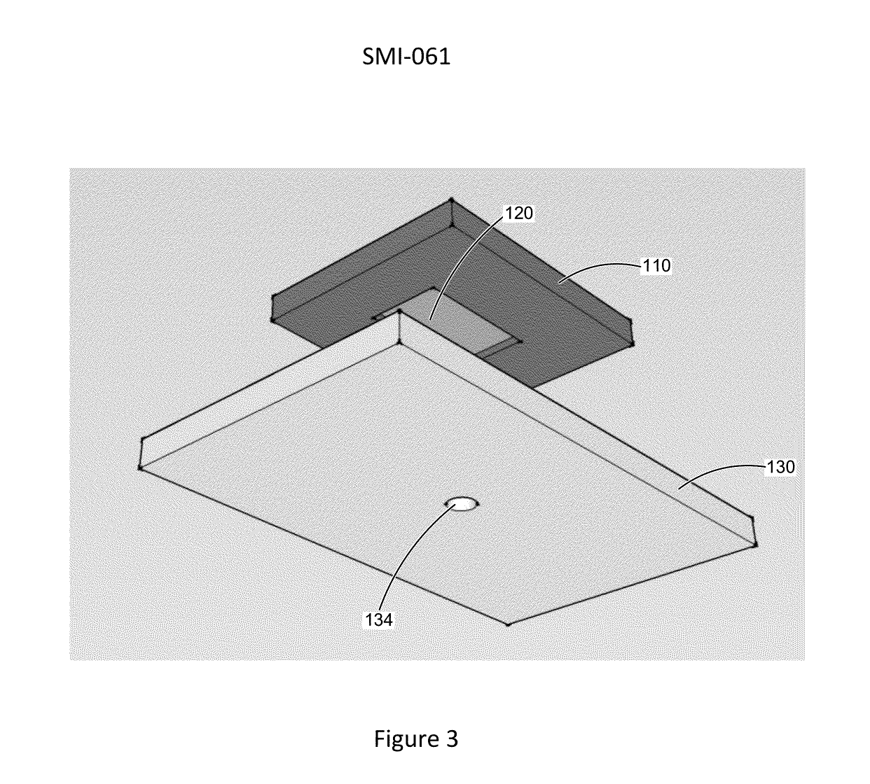

FIG. 3 is a bottom-view illustrating portions of a pressure sensing device according to an embodiment of the present invention. In this example, a first die or wafer portion 120 may be a pressure sensor having a cavity formed at an underside of diaphragm 120. The first die or wafer portion 110 may be mounted on application-specific integrated circuit 130. Application-specific integrated circuit 130 may include passage 134. When pressure sensor 110 is mounted on application-specific integrated circuit 130, the cavity (partly) defined by diaphragm 120 may be aligned to an opening of passage 134 in a top side of application-specific integrated circuit 130.

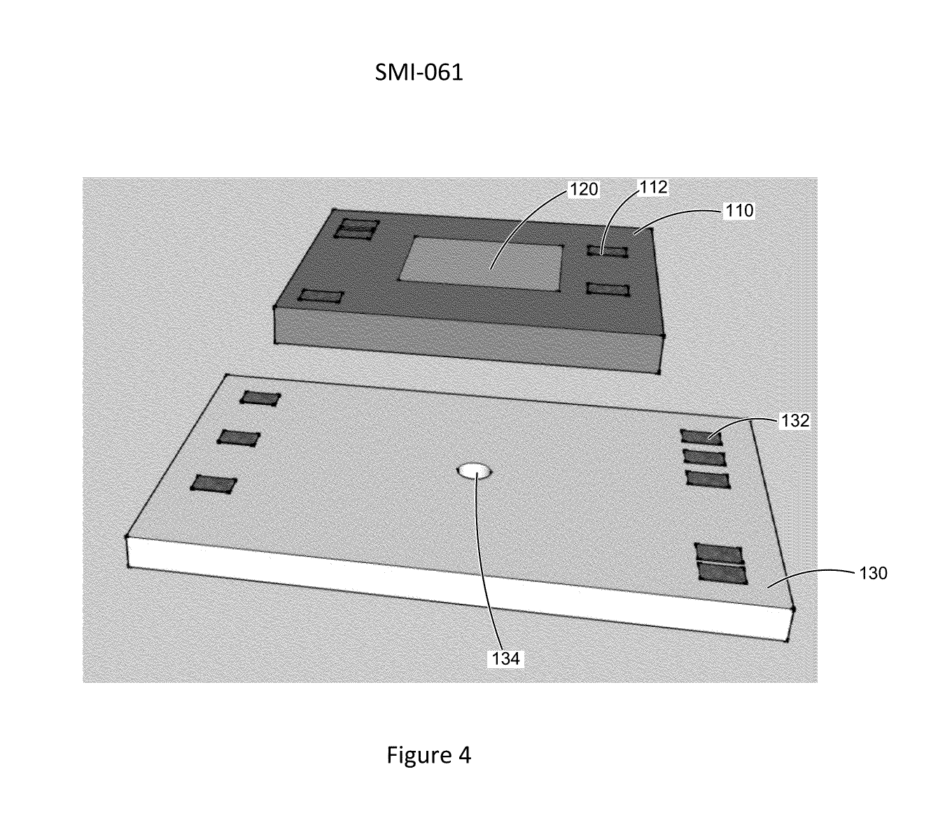

FIG. 4 is a top view illustrating portions of a pressure sensing device according to an embodiment present invention. Again, pressure sensor 110 may include diaphragm 120 surrounded by a frame supporting pads 112. Application-specific integrated circuit 130 may include pads 132 and passage 134. Pressure sensor 110 may be placed on application-specific integrated circuit 130 such that a cavity defined by diaphragm 120 is at least approximately aligned with an opening of passage 134 in a top side of application-specific integrated circuit 130.

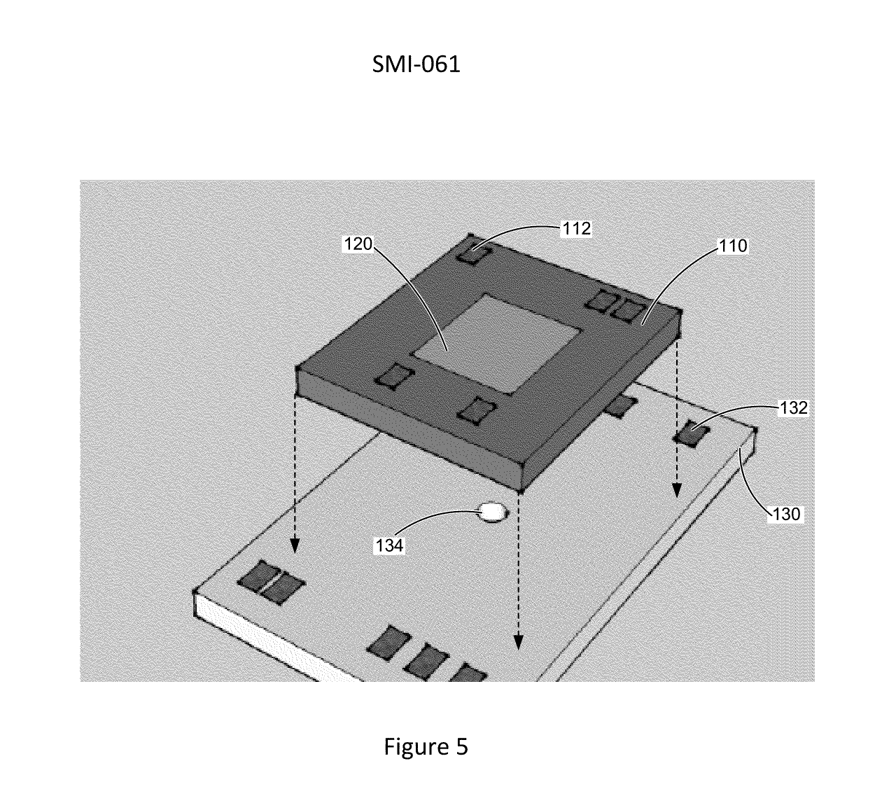

FIG. 5 illustrates a pressure sensor being placed on an application-specific integrated circuit according to an embodiment of the present invention. Again, pressure sensor 110 may include diaphragm 120 surrounded by a frame supporting pads 112. Application-specific integrated circuit 130 may include pads 132 and opening 134. Pressure sensor 110 may be attached to application-specific integrated circuit 130 using an adhesive, such as silicone including RTV silicone, epoxy, or other appropriate adhesive.

Again, pressure sensor 110 and application-specific integrated circuit 130 may be attached to each other and to a package or module using pads and bond wires, solder bumps, or other appropriate packaging techniques. An example illustrating bond wires and pads is shown in the following figure.

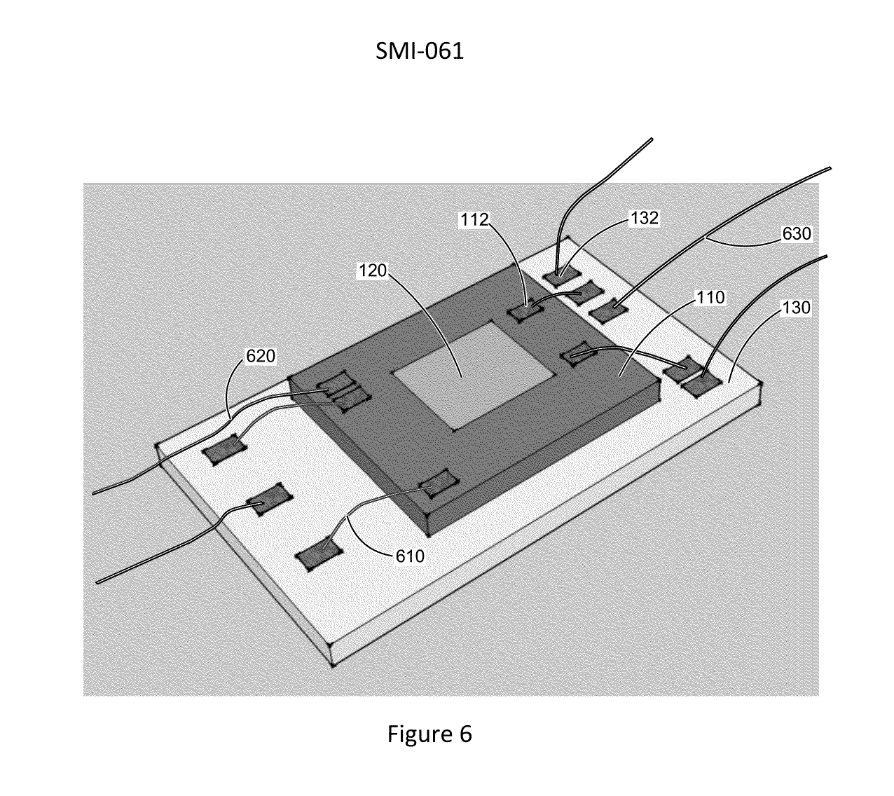

FIG. 6 illustrates a portion of a pressure sensor according to an embodiment of the present invention. Pressure sensor 110 may include diaphragm 120 by a frame supporting pads 112. Application-specific integrated circuit 130 may include pads 132. Pads 132 may be connected to pads 112 on pressure sensor 110 via bond wires 610. Pads 112 on pressure sensor 110 may connect to a package lead frame, pin, contact or other structure via bond wire 620. Pads 132 on application-specific integrated circuit 130 may connect to a package lead frame, pin, contact, or other structure, via bond wire 630.

As pressure sensor 110 may be mounted on application-specific integrated circuit 130, other circuits, die, or components may be mounted on either or both pressure sensor 110 and application-specific integrated circuit 130. An example is shown in the following figure.

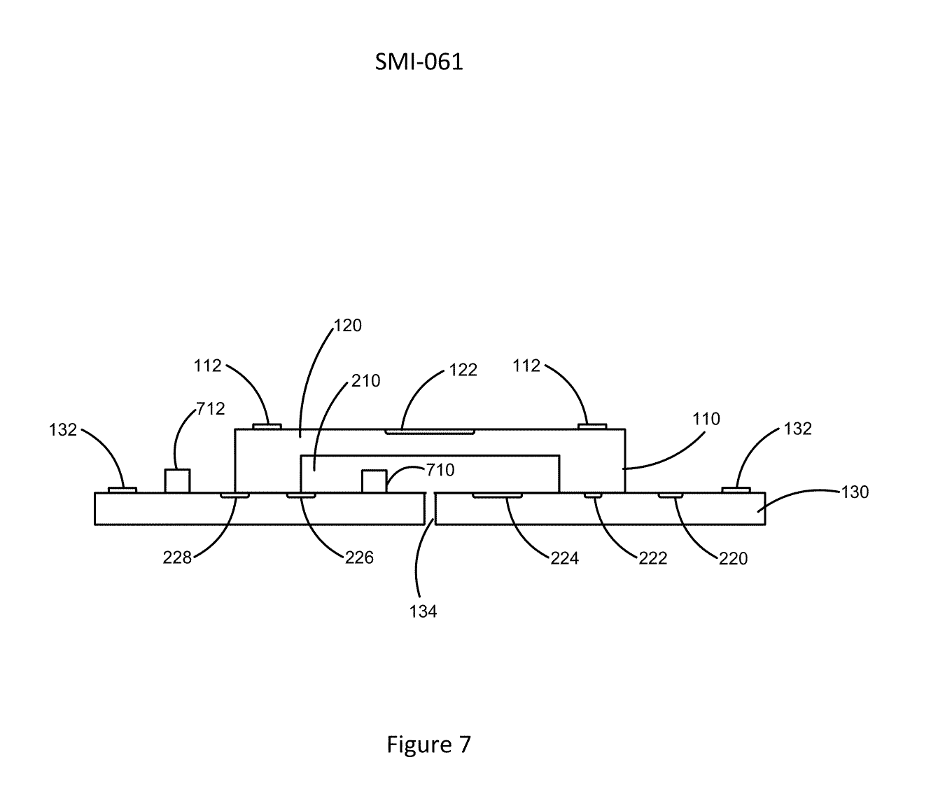

FIG. 7 illustrates a side view of a pressure sensing device according to an embodiment of the present invention. Again, pressure sensor 110 may include diaphragm 120 surrounded by a frame supporting one or more pads 112. One or more components 122 may be located on diaphragm 120. Diaphragm 120, the inner walls of the frame, and a top surface of application-specific integrated circuit 130 may define cavity 210.

Application-specific integrated circuit 130 may include passage 134, as before. One or more components 220, 222, 224, 226, and 228, may be located on a top surface of application-specific integrated circuit 130. One or more components or die 710 and 712 may also be located on either or both pressure sensor 110 and application-specific integrated circuit 130. In this example, component 710 may reside in cavity 210, while component 712 may reside on application-specific integrated circuit 130 in an area not covered by pressure sensor 110.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A pressure sensing device comprising:
a first wafer portion comprising a diaphragm formed in a top side of the first wafer portion, the diaphragm supported by a frame, the diaphragm and frame forming a cavity; and
a second wafer portion attached to a bottom side of the first wafer portion at a bottom of the frame, the second wafer having a passage from a bottom side to a top side, the passage aligned such that an opening of the passage at the top side of the second wafer is under the diaphragm of the first wafer portion.

2. The pressure sensing device of claim 1 wherein the frame of the first wafer portion surrounds the opening of the passage at the top side of the wafer.

3. The pressure sensing device of claim 2 further comprising:
a first circuit component formed in a top side of the second wafer portion, the first circuit component located in an area on the top side of the second wafer not covered by the first wafer portion.

4. The pressure sensing device of claim 3 further comprising:
a second circuit component formed in a top side of the second wafer portion, the second circuit component located in an area on the top side of the second wafer portion under the first wafer portion.

5. The pressure sensing device of claim 4 further comprising:
a second circuit component formed in a top side of the second wafer portion, the second circuit component located in an area on the top side of the second wafer portion under the diaphragm and surrounded by the frame of the first wafer portion.

6. The pressure sensing device of claim 4 further comprising:
a third circuit component formed in a top side of the second wafer portion, the third circuit component located under the frame of the first wafer portion.

7. The pressure sensing device of claim 4 further comprising:
a third circuit component formed in a top side of the second wafer portion, the third circuit component located in an area on the top side of the second wafer portion partially under the diaphragm and partially under the frame of the first wafer portion.

8. The pressure sensing device of claim 4 further comprising:
a third circuit component formed in a top side of the second wafer portion, the third circuit component located in an area on the top side of the second wafer portion partially under the diaphragm and partially in an area on the top side of the second wafer not covered by the first wafer portion.

9. The pressure sensing device of claim 4 wherein the frame surrounds the diaphragm.

10. The pressure sensing device of claim 9 wherein the first wafer portion further comprises a plurality of pads located on the frame around the diaphragm and the second wafer portion further comprises a second plurality of pads on the top side of the second wafer portion.

11. A pressure sensing device comprising:
a first wafer portion comprising a diaphragm surrounded by a frame and attached to the frame at a top of the frame, a pressure sensing circuit located at least substantially on the diaphragm; and
a second wafer portion attached to a bottom of the frame to form a cavity, the cavity defined by a bottom of the diaphragm, an inner side wall of the frame, and a first area of a top of the second wafer portion, the second wafer having a passage from a bottom side to a top side, the passage having an opening of the passage in the first area of the second wafer.

12. The pressure sensing device of claim 11 wherein the opening of the passage is under the diaphragm of the first wafer portion.

13. The pressure sensing device of claim 12 further comprising:
a first circuit component formed in a top side of the second wafer portion, the first circuit component located in an area on the top side of the second wafer not covered by the first wafer portion.

14. The pressure sensing device of claim 13 further comprising:
a second circuit component formed in a top side of the second wafer portion, the second circuit component located in an area on the top side of the second wafer portion under the first wafer portion.

15. The pressure sensing device of claim 4 further comprising:
a second circuit component formed in a top side of the second wafer portion, the second circuit component located in the first area on the top side of the second wafer portion.

16. A method of manufacturing a pressure sensing device comprising:
forming a first wafer portion comprising a pressure sensor;
forming a second wafer portion comprising an application-specific integrated circuit
forming a passage through the second wafer portion from a bottom side of the second wafer portion to a top side of the second wafer portion; and
attaching a bottom of the first wafer portion to a top of the second wafer portion such that an opening of the passage in the top side of the second wafer portion is under the first wafer portion.

17. The method of claim 16 wherein the first wafer portion is attached to a top of the second wafer portion using a soft die attach.

18. The method of claim 16 wherein the first wafer portion is attached to a top of the second wafer portion using silicone.

19. The method of claim 17 wherein the application-specific integrated circuit includes one or more of an amplifier, analog-to-digital converter, digital-to-analog converter, multiplexer, memory, and logic components.

20. The method of claim 17 wherein the passage is formed using a deep-reactive ion etch.
